(19) United States
(12) Patent Application Publication
(10) Pub. No.: US 2019/0062594 A1
(43) Pub. Date: Feb. 28, 2019

(54) CHEMICAL MECHANICAL POLISHING SLURRY AND APPLICATION THEREOF

(71) Applicant: Anji Microelectronics Technology (Shanghai) Co.,Ltd., Shanghai (CN)

(72) Inventors: Ying YAO, Shanghai (CN); Jianfen JING, Shanghai (CN); Xinyuan CAI, Shanghai (CN); Tengfei QIU, Shanghai (CN); Junya YANG, Shanghai (CN)

(21) Appl. No.: 16/067,360

(22) PCT Filed: Dec. 23, 2016
(86) PCT No.: PCT/CN2016/111722

§ 371 Date: Nov. 5, 2018

(30) Foreign Application Priority Data
Dec. 31, 2015 (CN) 201511026801.6

(51) Int. Cl. C09G 1/02; B24B 37/04; H01L 21/3105; H01L 21/321; H01L 21/768; C09K 3/14

(52) U.S. Cl. CPC C09G 1/02; B24B 37/044; H01L 21/31053; C09K 3/1409; H01L 21/7684; H01L 21/76819; H01L 21/3212

(57) ABSTRACT

A chemical mechanical polishing slurry and an application thereof are described herein. The polishing slurry includes: (a) grinding particles, (b) aminosilane coupling agent, (c) azole compound, (d) complexing agent, (e) organic phosphoric acid, (f) oxidizing agent, and (g) water. The chemical mechanical polishing slurry can be used for polishing through-silicon vias (TSV) and IC blocking layers, and is capable of meeting the requirements with respect to polishing rates and selection ratio for various materials. The polishing slurry has a strong correcting ability for a surface of a silicon wafer device, can achieve rapid planarization, and prevent local and overall corrosion that occurs in the metal polishing process, thus improving work efficiency and reducing production cost.

### TECHNOLOGY FIELD

The present invention relates to a chemical mechanical polishing slurry for polishing TSV and IC barrier layers.

### BACKGROUND

During the manufacture of integrated circuits, thousands of structural units are often built on a silicon wafer substrate, and these structural units further form functional circuits and components through multilayer metal interconnects. In a multilayer metal interconnect structure, Silicon Dioxide Silicon Dioxide or Silicon Dioxide Silicon Dioxide doped with other elements is filled among the metal wires as an interlayer dielectric (ILD). With the development of metal interconnection technology of integrated circuit and the increase of the number of wiring layers, chemical mechanical polishing (CMP) has been widely used for surface planarization in the process of chip manufacture. These flatted chip surfaces facilitate the production of multilayer integrated circuits and prevent distortions caused by coating the dielectric layer on uneven surfaces.

The CMP process is polishing the surface of the integrated circuit using an abrasive-containing mixture and a polishing pad. In the typical chemical mechanical polishing method, make the substrate directly touch with the rotating polishing pad and press the back of the substrate by a load. During the polishing process, make the platen and the pad, while keep a down force on the back of the substrate, then apply an abrasive and chemical solution (usually called a polishing slurry) to the pad, the polishing slurry react with the film being polished, which initiate the polishing process.

Silicon Dioxide Silicon Dioxide is commonly used as dielectric material in integrated circuits. Removal of a Silicon Dioxide Silicon Dioxide dielectric layer was involved in many polishing processes, for example, in inter metal dielectric CMP process, the polishing slurry is mainly used to remove and planarize the oxide dielectric layer ; in shallow trench isolation CMP process, the polishing slurry is mainly used to remove oxide dielectric layer and stop on Silicon Nitride film; in barrier CMP process, the polishing slurry is used to remove Silicon Dioxide Silicon Dioxide, Copper and barrier layer; in the through-silicon via (TSV) CMP process, the formation of the via also needs to remove Silicon Dioxide using the polishing slurry. In these CMP processes, a high removal rate of the oxide dielectric layer is required to ensure the throughput. Usually, removal rate of oxide film is increased by increasing the abrasive content, which will result in high cost. And also, slurry can't be concentrated with high abrasive content. The prior art WO2010033156A2 uses quaternary ammonium salts, quaternary phosphonium salts, and aminosilane compounds to increase the removal rate of silica materials in the polishing process.

In CMP process, in addition to strictly control surface defectivities and prevent metal corrosion, it is also necessary to have a low dishing and good polishing uniformity to ensure more reliable electrical performance. Especially, in barrier CMP process, the barrier layer needs to be removed fast at low polishing pressure. The invention aims to provide a highly concentrated polishing slurry which is suitable for polishing barrier in TSV and IC Copper interconnect process. The polishing slurry has a high barrier removal rate under mild polishing conditions and can control dishing, metal corrosion and surface defects well.

### SUMMARY OF THE INVENTION

The present invention provides a chemical mechanical polishing slurry containing abrasive particles, aminosilane coupling agent, azole compound, a complexing agent, organic phosphoric acid, oxidizing agent, and water.

In the chemical mechanical polishing slurry of the present invention, wherein the abrasive particles are nano-silica, of which the mass percentage content is 0.5% to 30%, preferably is 2-20%; of which the particle size is 20-200 nm, preferably is 30-150 nm.

The structural formula of the aminosilane coupling agent in the chemical mechanical polishing slurry of the present invention is as follows:

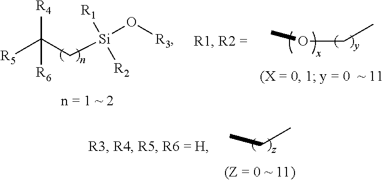

In the chemical mechanical polishing slurry of the present invention, wherein the aminosilane coupling agent can be aminoethyl methyl diethoxy silane, aminoethyl methyl dimethoxy silane, aminoethyl dimethyl methoxy silane, aminopropyl methyl diethoxy silane, aminopropyl methyl dimethoxy silane, aminopropyl dimethyl methoxy silane or aminopropyl trimethoxy silane. The mass percentage content of the aminosilane coupling agent is 0.005-0.3%, preferably is 0.01-0.2%.

In the chemical mechanical polishing slurry of the present invention, wherein the azole compound can be one or more compounds selected from benzotriazole, methylbenzotriazole, 5-phenyltetrazole, benzimidazole, 1,2,4-triazole, 3-amino-1,2,4-triazole, and 4-amino-1,2,4-triazole. The mass percentage content of the azole compound is 0.001%-1%, preferably is 0.01-0.3%

In the chemical mechanical polishing slurry of the present invention, wherein the complexing agent is one or more compounds selected from an organic acid and an amino acid compound. Preferably is one or more compounds selected from acetic acid, malonic acid, succinic acid, citric acid, glycine, proline, tyrosine, glutamate, lysine and arginine. The mass percentage content of the complexing agent is 0.01-2%, preferably is 0.05-1%.

In the chemical mechanical polishing slurry of the present invention, wherein the organic phosphoric acid can be hydroxyl ethylidene diphosphonic acid, amino trimethylene phosphonic acid, ethylene diamine tetra methylene phosphonic acid, diethylene triamine pentamethylene phosphonic acid, 2-phosphonobutane-1,2,4-triphosphonic acid or poly amino polyether methylene phosphonic acid. The mass percentage content of the organic phosphoric acid is 0.01-1%, preferably is 0.1-0.5%.

In the chemical mechanical polishing slurry of the present invention, wherein the oxidizing agent is one or more compounds selected from hydrogen peroxide, peracetic acid, potassium persulfate and ammonium persulfate. The mass percentage content of the oxidizing agent is 0.01-5%. Preferably is 0.1-2%.

The pH value of the chemical mechanical polishing slurry described in the present invention is 3-6, preferably is 4-6.

The chemical mechanical polishing slurry of the present invention may also contain other additives of the field, such as a pH regulator and a bactericide. The residue mass of the chemical mechanical polishing slurry is water.

The chemical mechanical polishing slurry of the present invention can be prepared as the following method: mix uniformly and proportionally the components except oxidizer, adjust the pH to a desired value using pH adjustor (such as KOH or HNO₃). Then add the oxidizer to the above mixture and mix uniformly before using it.

The reagents and raw materials used in the present invention are all commercially available.

Another aspect of the present invention relates to the application of the chemical mechanical polishing slurry for polishing TSV and IC barrier layers. The polishing slurry has a strong topography corrective capability for the surface of device wafers, and can suppress the local and overall corrosion in polishing process.

The technical effect of the present invention lies in:

1) The present invention uses the nanoparticle modified by the aminosilane coupling agent as abrasive particle, so that the polishing slurry has an excellent removal rate of Silicon Dioxide. The polishing slurry can meet the removal rate requirements on Silicon Dioxide (TEOS), Silicon Nitride, low dielectric constant materials (BD), Tantalum, Titanium and Copper in the barrier CMP process.

2) The polishing slurry of the present invention can be highly concentrated for easy storage and transportation.

### DETAILED DESCRIPTION

The advantages of the present invention are further illustrated by the following specific embodiments, but the protection scope of the present invention is not limited to the following embodiments. The respective polishing slurry of each embodiments is prepared by following steps: uniformly mix the composition and water, then adjust pH to a suitable value with Nitric Acid or Potassium Hydroxide. The contents in the table refer to mass percentages content.

TABLE 1
Components and contents of the polishing slurry of comparison and the present invention

| | Abrasive | | | | | | | | | | | | | |
|---|---|---|---|---|---|---|---|---|---|---|---|---|---|---|
| | particles | | | Aminosilane | | Complexing | | Azole | | Organic | | Oxidizing | | |
| | Average | | | reagent | | agent | | compound | | Phosphoric Acid | | agent | | |
| polishing | particle | | Con- | Sub- | Con- | Sub- | Con- | Sub- | Con- | Sub- | Con- | Sub- | Con- | |
| slurry | size | | tent(%) | stance | tent(%) | stance | tent(%) | stance | tent(%) | stance | tent(%) | stance | tent(%) | pH |
| Comparation | 90 | nm | 6 | | | | | | | | | | | 5 |
| 1 | | | | | | | | | | | | | | |
| Comparation | 90 | nm | 6 | Amino- | 0.05 | | | | | | | | | 5 |
| 2 | | | | propyl- | | | | | | | | | | |
| | | | | methyl- | | | | | | | | | | |
| | | | | diethoxy- | | | | | | | | | | |
| | | | | silane | | | | | | | | | | |
| 1 | 90 | nm | 6 | Amino- | 0.05 | Glutamate | 0.5 | Benzo- | 0.1 | Hydroxy- | 0.1 | hydrogen | 1 | 5 |
| | | | | propyl- | | | | triazole | | ethylene | | peroxide | | |
| | | | | methyl- | | | | | | diphos- | | | | |
| | | | | diethoxy- | | | | | | phonic | | | | |
| | | | | silane | | | | | | acid | | | | |
| 2 | 90 | nm | 6 | Amino- | 0.03 | Glycine | 0.2 | Benzo- | 0.05 | Amino- | 0.2 | hydrogen | 0.5 | 5 |
| | | | | propyl- | | | | triazole | | trimethylene | | peroxide | | |
| | | | | methyl- | | | | | | phosphonic | | | | |
| | | | | diethoxy- | | | | | | acid | | | | |
| | | | | silane | | | | | | | | | | |
| 3 | 90 | nm | 6 | Amino- | 0.08 | Glycine | 0.1 | Methyl- | 0.01 | Ethylene- | 0.5 | hydrogen | 0.1 | 5 |
| | | | | propyl- | | | | benzo- | | diamine | | peroxide | | |
| | | | | methyl- | | | | triazole | | tetra- | | | | |
| | | | | diethoxy- | | | | | | methylene | | | | |
| | | | | silane | | | | | | phosphonic | | | | |
| | | | | | | | | | | acid | | | | |
| 4 | 90 | nm | 6 | Amino- | 0.1 | Tyrosine | 1 | Benzo- | 0.3 | Diethylene- | 0.1 | hydrogen | 2 | 6 |
| | | | | propyl- | | | | triazole | | triamine | | peroxide | | |
| | | | | tri- | | | | | | penta- | | | | |
| | | | | methoxy- | | | | | | methylene | | | | |
| | | | | silane | | | | | | phosphonic | | | | |
| | | | | | | | | | | acid | | | | |
| 5 | 30 | nm | 20 | Amino- | 0.01 | Arginine | 0.8 | 5- | 0.15 | 2- | 0.1 | hydrogen | 0.8 | 6 |
| | | | | propyl- | | | | phenyl- | | phosphono- | | peroxide | | |
| | | | | methyl- | | | | tetra- | | butane-1,2,4- | | | | |
| | | | | diethoxy- | | | | zolium | | triphos- | | | | |
| | | | | silane | | | | | | phonic | | | | |
| | | | | | | | | | | acid | | | | |
| 6 | 50 | nm | 10 | Amino- | 0.02 | Lysine | 0.5 | Benz- | 0.2 | Polyamino- | 0.2 | hydrogen | 1.5 | 6 |
| | | | | propyl- | | | | imid- | | polyether- | | peroxide | | |
| | | | | methyl- | | | | azole | | methylene- | | | | |
| | | | | diethoxy- | | | | | | methylene- | | | | |
| | | | | silane | | | | | | phosphonic | | | | |
| | | | | | | | | | | acid | | | | |
| 7 | 120 | nm | 4 | Amino- | 0.15 | Glycine | 0.05 | 1,2,4- | 0.1 | Hydroxy- | 0.5 | hydrogen | 0.2 | 4 |
| | | | | propyl- | | | | triazole | | ethylidene | | peroxide | | |
| | | | | methyl- | | | | | | diphos- | | | | |
| | | | | diethoxy- | | | | | | phonic | | | | |
| | | | | silane | | | | | | acid | | | | |
| 8 | 150 | nm | 2 | Amino- | 0.2 | Tyrosine | 1 | 3- | 0.3 | 2- | 0.2 | hydrogen | 0.3 | 4 |
| | | | | propyl- | | | | amino- | | phosphono- | | peroxide | | |
| | | | | tri- | | | | 1,2,4 | | butane-1,2,4- | | | | |
| | | | | methoxy- | | | | triazole | | triphos- | | | | |
| | | | | silane | | | | | | phonic | | | | |
| | | | | | | | | | | acid | | | | |
| 9 | 90 | nm | 5 | Amino- | 0.05 | Valine | 0.2 | 4- | 0.2 | Ethylene- | 0.2 | hydrogen | 0.5 | 4 |
| | | | | propyl- | | | | amino- | | diamine- | | peroxide | | |
| | | | | methyl- | | | | 1,2,4 | | tetra- | | | | |
| | | | | diethoxy- | | | | triazole | | methylene- | | | | |
| | | | | silane | | | | | | phosphonic | | | | |
| | | | | | | | | | | acid | | | | |
| 10 | 90 | nm | 5 | Amino- | 0.05 | Succinic | 0.1 | Benzo- | 0.05 | 2- | 0.2 | Potassium | 1.5 | 5 |
| | | | | propyl- | | acid | | triazole | | phosphono- | | persulfate | | |
| | | | | methyl- | | | | | | butane-1,2,4- | | | | |
| | | | | diethoxy- | | | | | | triphos- | | | | |
| | | | | silane | | | | | | phonic | | | | |
| | | | | | | | | | | acid | | | | |
| 11 | 90 | nm | 5 | Amino- | 0.05 | Malonate | 0.2 | Benzo- | 0.05 | 2- | 0.3 | Ammonium | 0.1 | 6 |
| | | | | propyl- | | | | triazole | | phosphono- | | persulfate | | |
| | | | | methyl- | | | | | | butane-1,2,4- | | | | |
| | | | | diethoxy- | | | | | | triphos- | | | | |
| | | | | silane | | | | | | phonic | | | | |
| | | | | | | | | | | acid | | | | |
| 12 | 20 | nm | 30 | Amino- | 0.005 | Citric | 0.01 | Benzo- | 0.001 | 2- | 1 | peracetic | 5 | 3 |
| | | | | propyl- | | acid | | triazole | | phosphono- | | acid | | |
| | | | | methyl- | | | | | | butane-1,2,4- | | | | |
| | | | | diethoxy- | | | | | | triphos- | | | | |
| | | | | silane | | | | | | phonic | | | | |
| | | | | | | | | | | acid | | | | |
| 13 | 200 | nm | 0.5 | Amino- | 0.3 | Acetic | 2 | Benzo- | 1 | Hydroxy- | 0.01 | hydrogen | 0.01 | 5 |
| | | | | propyl- | | acid | | triazole | | ethylene | | peroxide | | |
| | | | | methyl- | | | | | | diphos- | | | | |
| | | | | diethoxy- | | | | | | phonic | | | | |
| | | | | silane | | | | | | acid | | | | |

### Embodiment 1

The polishing performance of the above composition was studied in Embodiment 1. The mixed composition was used to polish under the following condition: Mirra, the polishing pad is IC1010 pad, the down force is 3.0 psi, the rotation speed of polishing platen/head is 93/87 rpm, the slurry flow rate is 150 ml/min, and the polishing time is 1 minute. The polishing results are shown in Table 2.

TABLE 2
Removal rate of the comparison 1 and the polishing slurry 1~13
of the present invention respectively on Silicon Dioxide (TEOS),
Copper (Cu), Tantalum (Ta), Titanium (Ti), Silicon Nitride
(SiN), and low dielectric constant material (BD).

| Polishing | Removal rate (Å/min) | | | | | |
|---|---|---|---|---|---|---|
| slurry | TEOS | Cu | Ta | Ti | SiN | BD1 |
| Compar- | 455 | | | | 150 | 95 |
| ison 1 | | | | | | |
| Compar- | 1947 | | | | 172 | 286 |
| ison 2 | | | | | | |
| 1 | 1956 | 725 | 1598 | 1674 | 136 | 356 |
| 2 | 1846 | 816 | 1451 | 1510 | 129 | 296 |
| 3 | 2173 | 789 | 1523 | 1615 | 154 | 324 |
| 4 | 2063 | 747 | 1612 | 1698 | 163 | 352 |
| 5 | 2177 | 821 | 1732 | 1825 | 149 | 379 |
| 6 | 2071 | 799 | 1647 | 1724 | 158 | 405 |
| 7 | 1897 | 687 | 1439 | 1517 | 123 | 309 |
| 8 | 1675 | 538 | 1267 | 1329 | 101 | 286 |
| 9 | 1913 | 769 | 1426 | 1568 | 112 | 299 |
| 10 | 1932 | 873 | 1432 | 1597 | 119 | 287 |
| 11 | 1899 | 903 | 1455 | 1601 | 109 | 257 |
| 12 | 1211 | 978 | 1119 | 1223 | 87 | 219 |
| 13 | 1436 | 789 | 1097 | 1115 | 79 | 232 |

As shown in Table 2, comparing with the comparison slurry 1 and 2, the slurry of the present invention can achieve a higher Ta, Ti and TEOS removal rates and lower SiN removal rate, which can ensure that the polishing can be better stopped on the surface of Silicon Nitride.

In addition, the compositions 7 to 11 contain a low abrasive particles content. All of them can be made into highly concentrated polishing slurry with excellent storage stability and polishing stability.

### Embodiment 2

The polishing performance of the above composition under low pressure was studied in Embodiment 2. The mixed composition was used to polish under the following condition: Mirra, the polishing pad is Fujibo pad, down force is 1.5 psi, the rotation speed of polishing platen/head is 93/87 rpm, the slurry flow rate is 150 ml/min, and the polishing time is 1 minute. The polishing results are shown in Table 3.

TABLE 3
The removal rate of the comparison polishing slurry and polishing
slurry 1~6 of the present invention respectively on Silicon
Dioxide (TEOS), Copper (Cu), Tantalum (Ta), Titanium (Ti), Silicon
Nitride (SiN), and low dielectric constant material (BD).

| Polishing | Removal rate (Å/min) | | | | | |
|---|---|---|---|---|---|---|
| slurry | TEOS | Cu | Ta | Ti | SiN | BD1 |
| Compar- | 215 | | | | 73 | 48 |
| ison 1 | | | | | | |
| Compar- | 956 | | | | 87 | 221 |
| ison 2 | | | | | | |
| 1 | 978 | 243 | 769 | 947 | 72 | 312 |
| 2 | 912 | 301 | 741 | 863 | 69 | 246 |
| 3 | 1156 | 287 | 752 | 904 | 81 | 287 |
| 4 | 1075 | 269 | 798 | 957 | 98 | 324 |
| 5 | 1123 | 287 | 801 | 1002 | 82 | 351 |
| 6 | 1086 | 276 | 845 | 978 | 84 | 367 |

As shown in Table 3, comparing with the comparison polishing slurry 1 and 2, the polishing slurry of the present invention can achieve a higher removal rate of Tantalum, Titanium and silicon oxide (TEOS), and can meet the requirements to the removal rate of Silicon Dioxide (TEOS), Silicon Nitride, low dielectric constant material (BD), Tantalum Titanium and Copper in the barrier layer polishing process.

### Embodiment 3

Use the comparison polishing slurry 1 and polishing slurry 1-2 of the present invention to polish the TSV patterned wafers under the following conditions: Mirra, the polishing pad is IC1010 pad, down force is 3.0 psi, the rotation speed of polishing platen/head is 93/87 rpm, the slurry flow rate is 150 ml/min, and the polishing time is 1 minute.

TABLE 4
Dishing Correction capability of the comparison
polishing slurry 1 and the polishing slurry 1~2 of
the present invention on TSV patterned wafers.

| | Dishing (Å) | | |
|---|---|---|---|
| Polishing | Before | After | |
| slurry | polishing | polishing | Δ(Å) |
| compar- | 1702 | 1564 | 138 |
| ison 1 | | | |
| 1 | 2165 | 114 | 2051 |
| 2 | 1939 | 86 | 1853 |

in Table 4, wherein “Dishing” refers to the Cu dishing on Cu via, “Δ(Å)” refers to the dishing correction which equals to dishing before barrier polishing minus dishing after barrier polishing.

As shown in Table 4: Compared with the comparison polishing slurry, the polishing slurry of the present invention has stronger dishing correction capability and obtains better surface topography on patterned wafers.

### Embodiment 4

Use the comparison polishing slurry 1 and polishing slurry 1-2 of the present invention to polish Copper patterned wafers under the following conditions: Mirra, the polishing pad is Fujibo pad, down force is 1.5 psi, the rotation speed of polishing platen/head is93/87 rpm, slurry flow rate is 150 ml/min, and the polishing time is 1 minute.

TABLE 5
Dishing/Erosion Correction capability of comparison
polishing slurry 1 and polishing slurry 1~2 of
the present invention on Copper patterned wafers

| | Dishing(Å) | | | Erosion(Å) | | |
|---|---|---|---|---|---|---|
| Polishing | Before | After | | Before | After | |
| slurry | polishing | polishing | Δ(Å) | polishing | polishing | Δ(Å) |
| compar- | 447 | 412 | 35 | 345 | 321 | 24 |
| ison 1 | | | | | | |
| 1 | 457 | 109 | 348 | 323 | 90 | 233 |
| 2 | 498 | 126 | 372 | 356 | 107 | 249 |

In Table 5, wherein “Dishing” refers to the Cu dishing on Cu bond pad, “Erosion” refers to the Erosion of barrier layer on the fine Cu line area with 50% density , “Δ(Å)” refers to the topography correction which equals to dishing/erosion before barrier polishing minus dishing/erosion after barrier polishing.

Compared with the comparison polishing slurry 1, the polishing slurry of the present invention have stronger dishing/erosion correction capability and obtain better surface topography on patterned wafers.

The detail of the present invention has been fully described above, it should be understood that all the detail description above are just examples, but not the limitation of the present invention. Any equivalent modification or replacement of the present invention by the experienced persons in this field should be involved in the scope of the present invention. Therefore, the equivalent changes and modifications without departing from the spirit and scope of the present invention shall be involved in the scope of the present invention.

1. A chemical mechanical polishing slurry comprising abrasive particles, aminosilane coupling agent, azole compound, complexing agent, organic phosphoric acid, oxidizing agent, and water.

2. The chemical mechanical polishing slurry according to claim 1, wherein the abrasive particles are nano-silica.

3. The chemical mechanical polishing slurry according to claim 2, wherein the particle size of the nano-silica is 20-200 nm.

4. The chemical mechanical polishing slurry according to claim 2, wherein the particle size of the nano-silica is 30-150 nm.

5. The chemical mechanical polishing slurry according to claim 1, wherein the mass percentage content of the abrasive particles is 0.5% to 30%.

6. The chemical mechanical polishing slurry according to claim 5, wherein the mass percentage content of the abrasive particles is 2-20%.

7. The chemical mechanical polishing slurry according to claim 1, wherein the formula of the aminosilane coupling agent is:

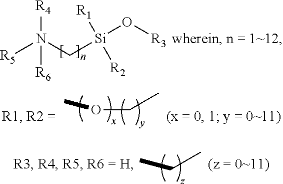

8. The chemical mechanical polishing slurry according to claim 7, wherein the aminosilane coupling agent is aminoethylmethyldiethoxysilane, aminoethylmethyldimethoxysilane, aminoethyldimethylmethoxysilane, aminopropylmethyldiethoxysilane, aminopropylmethyldimethoxysilane, aminopropyldimethylmethoxysilane or aminopropyltrimethoxysilane.

9. The chemical mechanical polishing slurry according to claim 1, wherein the mass percentage content of the aminosilane coupling agent is 0.005-0.3%.

10. The chemical mechanical polishing slurry according to claim 9, wherein the mass percentage content of the aminosilane coupling agent is 0.01-0.2%.

11. The chemical mechanical polishing slurry according to claim 1, wherein the azole compound is one or more compounds selected from the group consisting of benzotriazole, methylbenzotriazole, 5-phenyltetrazole, benzimidazole, 1,2,4-triazole, 3-amino-1,2,4-triazole, and 4-amino-1,2,4-triazole.

12. The chemical mechanical polishing slurry according to claim 1, wherein the mass percentage content of the azole compound is 0.001%-1%.

13. The chemical mechanical polishing slurry according to claim 12, wherein the mass percentage content of the azole compound is 0.01%-0.3%.

14. The chemical mechanical polishing slurry according to claim 1, wherein the complexing agent is one or more compounds selected from an organic acid and an amino acid compound.

15. The chemical mechanical polishing slurry according to claim 14, wherein the organic acid is one or more compounds selected from the group consisting of acetic acid, malonic acid, succinic acid and citric acid; and the amino acid compound is one or more compounds selected from the group consisting of glycine, proline, tyrosine, glutamate, lysine and arginine.

16. The chemical mechanical polishing slurry according to claim 1, wherein the mass percentage content of the complexing agent is 0.01-2%.

17. The chemical mechanical polishing slurry according to claim 16, wherein the mass percentage content of the complexing agent is 0.05-1%.

18. The chemical mechanical polishing slurry according to claim 1, wherein the organic phosphoric acid is hydroxyl ethylene diphosphonic acid, amino trimethylene phosphonic acid, ethylene diamine tetra methylene phosphonic acid, diethylene triamine pentamethylene phosphonic acid, 2-phosphonobutane-1,2,4-triphosphonic acid or poly amino polyether methylene phosphonic acid.

19. The chemical mechanical polishing slurry according to claim 1, wherein the mass percentage content of the organic phosphoric acid is 0.01-1%.

20. The chemical mechanical polishing slurry according to claim 19, wherein the mass percentage content of the organic phosphoric acid is 0.1-0.5%.

21. The chemical mechanical polishing slurry according to claim 1, wherein the oxidizing agent is one or more compounds selected from the group consisting of hydrogen peroxide, peracetic acid, potassium persulfate and ammonium persulfate.

22. The chemical mechanical polishing slurry according to claim 1, wherein the mass percentage content of the oxidizing agent is 0.01-5%.

23. The chemical mechanical polishing slurry according to claim 22, wherein the mass percentage content of the oxidizing agent is 0.1-2%.

24. The chemical mechanical polishing slurry according to claim 1, wherein the pH value of the polishing slurry is 3-6.

25. The chemical mechanical polishing slurry according to claim 24, wherein pH value of the polishing slurry is 4-6.

26. An application of a chemical mechanical polishing slurry according to claim 1 on polishing TSV and IC barrier layers.
